(19) United States
(12) Patent Application Publication
(10) Pub. No.: US 2009/0263592 A1
(43) Pub. Date: Oct. 22, 2009

(54) PLASMA-ENHANCED CHEMICAL VAPOR DEPOSITION OF ADVANCED LUBRICANT FOR THIN FILM STORAGE MEDIUM

(75) Inventors: Jianwei Liu, Fremont, CA (US); Michael Joseph Stirniman, Fremont, CA (US); Jing Gui, Fremont, CA (US); Lei Li, Wexford, PA (US); Yiao-Tee Hsia, Wexford, PA (US)

Correspondence Address: Shumaker & Sieffert, P.A., 1625 Radio Drive, Suite 300, Woodbury, MN, 55125, US

(73) Assignee: Seagate Technology LLC, Scotts Valley, CA (US)

(21) Appl. No.: 12/414,333

(22) Filed: Mar. 30, 2009

Related U.S. Application Data
(62) Division of application No. 10/911,738, filed on Aug. 5, 2004, now abandoned.

(51) Int. Cl. C23C 16/513

(52) U.S. Cl. 427/577; 427/569

(57) ABSTRACT

A magnetic recording medium including a solid lubricant film containing a plasma-enhanced chemical vapor deposited perfluoropolyether is disclosed. Preferably, the solid lubricant is formed in the presence of oxygen and longer fluorocarbon chain to form perfluoropolyether, thereby enhancing the chain flexibility perfluoropolyether and in the presence of a hydrocarbon to stabilize the process, thereby allowing process control.

This application is a Divisional of U.S. application Ser. No. 10/911,738, filed Aug. 5, 2004, the entire content of which is incorporated herein by reference.

### FIELD OF THE INVENTION

The present invention relates to a recording media having a solid lubricant formed by plasma-enhanced chemical vapor deposition (PECVD), wherein the solid lubricant has a good bonding on the recording media.

### BACKGROUND

Magnetic discs with magnetizable media are used for data storage in most all computer systems. Current magnetic hard disc drives operate with the read-write heads only a few nanometers above the disc surface and at rather high speeds, typically a few meters per second. Because the read-write heads can contact the disc surface during operation, a layer of lubricant is coated on the disc surface to reduce wear and friction.

FIG. 1 shows a disk recording medium and a cross section of a disc showing the difference between longitudinal and perpendicular recording. Even though FIG. 1 shows one side of the non-magnetic disk, magnetic recording layers are sputter deposited on both sides of the non-magnetic aluminum substrate of FIG. 1. Also, even though FIG. 1 shows an aluminum substrate, other embodiments include a substrate made of glass, glass-ceramic, NiP/aluminum, metal alloys, plastic/polymer material, ceramic, glass-polymer, composite materials or other non-magnetic materials.

Generally, the lubricant is applied to the disc surface by dipping the disc in a bath containing the lubricant. The bath typically contains the lubricant and a coating solvent to improve the coating characteristics of the lubricant, which is usually viscous oil. The discs are removed from the bath, and the solvent is allowed to evaporate, leaving a layer of lubricant on the disc surface.

The lubricant film on hard discs provides protection to the underlying magnetic alloy by preventing wear of the carbon overcoat. In addition, it works in combination with the overcoat to provide protection against corrosion of the underlying magnetic alloy.

Reliability of hard disks is depends on the durability of the thin film media. As the spacing between head disk is being reduced aggressively to improve area storage density, media are facing many severe technical obstacles, such as weak durability, heavy lubricant pickup, unmanageable stiction/friction, etc. Lubrication plays unquestionably an important role in overcoming these technical difficulties. Solid lubricant films have been considered as the ultimate solution to prevent lubricant pickup and for reduction of stiction. Moreover, the low volatility of solid lubricant makes such a lubricant extremely attractive for heat-assisted magnetic recording (HAMR). However, a major technical problem associated with solid lubricants is the weak durability and bonding of the lubricant to the underlying layers. Prior to this invention, all solid lubricants, including sputtered Teflon and dip-lubed solid lubricants, failed during industrial standard post-lubing processes, such as buffing, wiping and banishing.

### SUMMARY OF THE INVENTION

The invention relates a recording media having a solid lubricant formed by plasma-enhanced chemical vapor deposition, wherein the solid lubricant has a good bonding on the recording media, and the method of manufacturing such a recording media.

One embodiment of this invention relates to a magnetic recording medium comprising a solid lubricant film comprising a plasma-enhanced chemical vapor deposited perfluoropolyether. Another embodiment is a magnetic recording medium comprising a solid lubricant film comprising a polymer comprising C, F and O, wherein the solid lubricant film has a room temperature contact angle of greater than 75 degrees.

Preferably, the solid lubricant film comprises substantially no liquid component. Preferably, the solid lubricant film has a room temperature contact angle of greater than 75 degrees. Preferably, the plasma-enhanced chemical vapor deposited perfluoropolyether comprises

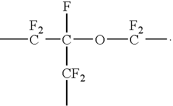

In one variation, the plasma-enhanced chemical vapor deposited perfluoropolyether comprises one oxygen per 1 to 10 carbon atoms. Preferably, the plasma-enhanced chemical vapor deposited perfluoropolyether comprises ether linkages between decafluoropentanyl segments. In another variation, the magnetic recording medium further comprises a magnetic recording layer and a carbon overcoat layer on the magnetic layer, wherein the solid lubricant film is located on the carbon overcoat layer.

Yet another embodiment is a method of manufacturing a magnetic recording medium forming a magnetic recording layer on a substrate, exposing a surface on the magnetic recording layer to an atmosphere comprising plasma and a fluorine-containing gas, and forming a plasma-enhanced chemical vapor deposited perfluoropolyether-containing layer on the magnetic recording layer. Preferably, the atmosphere further comprises oxygen and a hydrocarbon. Preferably, the atmosphere is maintained at a temperature of 150° C. or less. Preferably, the fluorine-containing gas is trifluoromethane and the hydrocarbon is a hydrocarbon gas.

Additional advantages of this invention will become readily apparent to those skilled in this art from the following detailed description, wherein only the preferred embodiments of this invention is shown and described, simply by way of illustration of the best mode contemplated for carrying out this invention. As will be realized, this invention a property of other and different embodiments, and its details are capable of modifications in various obvious respects, all without departing from this invention. Accordingly, the drawings and description are to be regarded as illustrative in nature and not as restrictive.

### BRIEF DESCRIPTION OF THE DRAWINGS

The present invention will be better understood by reference to the Detailed Description of the Invention when taken together with the attached drawings, wherein:

FIG. 1 shows a magnetic recording medium.

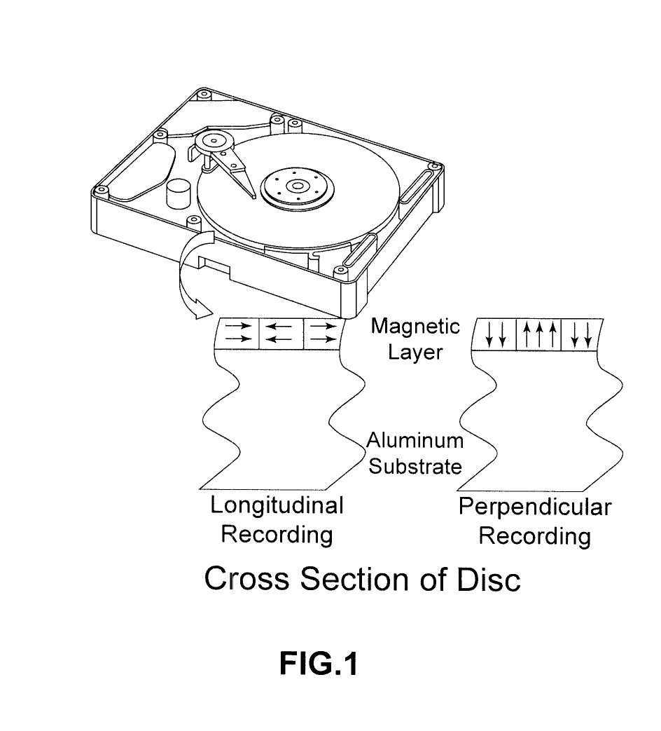

FIG. 2 shown an inline process for manufacturing magnetic recording media.

FIG. 3 shows a schematic PECVD polymerization of trifluoromethane to a cross-linked fluoropolymer.

FIG. 4 shows a schematic PECVD polymerization of trifluoromethane to a cross-linked perfluoropolyether in the presence of Oxygen.

FIG. 5 shows FTIR traces of PECVD perfluoropolyether and Zdol lubricant films.

FIG. 6 shows room temperature water contact angle of a PECVD perfluoropolyether lubricant film as a function of the film thickness.

FIG. 7 shows a picture of a PECVD film after post-lubing process, wherein the PECVD film was formed using only trifluoromethane in a plasma process.

FIG. 8 shows a picture of a PECVD film after post-lubing process, wherein the PECVD film was formed using trifluoromethane, oxygen and hexane in a plasma process.

### DETAILED DESCRIPTION OF THE INVENTION

The invention is directed to a method of coating a substrate, particularly recording media (recording discs), with a solid lubricant, which is also referred in the specification to as a “lube.” Lubricants typically are liquid and contain molecular weight components that range from several hundred Daltons to several thousand Daltons.

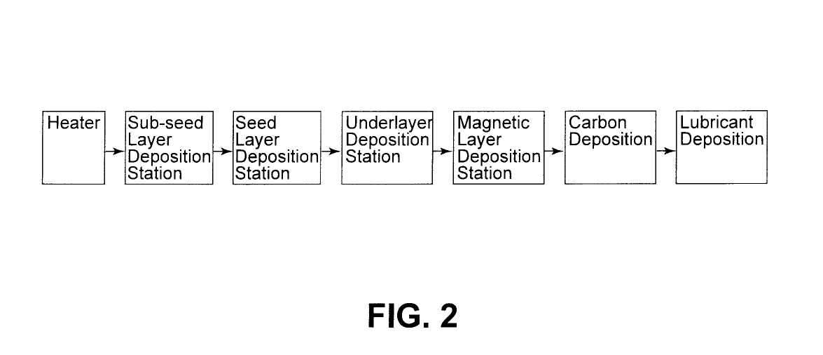

An inline process for manufacturing magnetic recording media is schematically illustrated in FIG. 2. The disc substrates travel sequentially from the heater to a sub-seed layer deposition station and a sub-seed layer is formed on the disc substrates. Then, the disc substrates travel to a seed layer station for deposition of the seed layer, typically NiAl. Subsequent to the deposition of the sub-seed layer and the seed layer, the disc substrates are passed through the underlayer deposition station wherein the underlayer is deposited. The discs are then passed to the magnetic layer deposition station and then to the protective carbon overcoat deposition station. Finally, the discs are passed through a lubricant film deposition station.

Almost all the manufacturing of the disks takes place in clean rooms, where the amount of dust in the atmosphere is kept very low, and is strictly controlled and monitored. The disk substrates come to the disk fabrication site packed in shipping cassettes. For certain types of media, the disk substrate has a polished nickel-coated surface. The substrates are preferably transferred to process cassettes to be moved from one process to another. Preferably, the cassettes are moved from one room to another on automatic guided vehicles to prevent contamination due to human contact.

The first step in preparing a disk for recording data is mechanical texturing by applying hard particle slurry to the polished surface of the substrate and to utilize proper tape materials on circumferential motion disk to create circumferentially texture grooves. This substrate treatment helps in depositing of a preferred underlayer crystallographic orientation and subsequently helps preferentially growth of magnetic recording material on the substrate. During the texturing process, small amounts of substrate materials get removed from surface of the disk and remain there. To remove this, the substrate is usually washed. Also, techniques for polishing the surface of the non-magnetic substrate of a recording medium use slurry polishing, which requires wash treatment. Thus, disk substrates are washed after texturing and polishing. However, wash defects could be one of the top yield detractors.

A final cleaning of the substrate is then done using a series of ultrasonic, megasonic and quick dump rinse (QDR) steps. At the end of the final clean, the substrate has an ultra-clean surface and is ready for the deposition of layers of magnetic media on the substrate. Preferably, the deposition is done by sputtering.

Sputtering is perhaps the most important step in the whole process of creating recording media. There are two types of sputtering: pass-by sputtering and static sputtering. In pass-by sputtering, disks are passed inside a vacuum chamber, where they are bombarded with the magnetic and non-magnetic materials that are deposited as one or more layers on the substrate. Static sputtering uses smaller machines, and each disk is picked up and sputtered individually.

The sputtering layers are deposited in what are called bombs, which are loaded onto the sputtering machine. The bombs are vacuum chambers with targets on either side. The substrate is lifted into the bomb and is bombarded with the sputtered material.

Sputtering leads to some particulates formation on the post sputter disks. These particulates need to be removed to ensure that they do not lead to the scratching between the head and substrate. Thus, a lube is preferably applied to the substrate surface as one of the top layers on the substrate.

Once a lube is applied, the substrates move to the buffing/burnishing stage, where the substrate is polished while it preferentially spins around a spindle. After buffing/burnishing, the substrate is wiped and a clean lube is evenly applied on the surface.

Subsequently, the disk is prepared and tested for quality thorough a three-stage process. First, a burnishing head passes over the surface, removing any bumps (asperities as the technical term goes). The glide head then goes over the disk, checking for remaining bumps, if any. Finally the certifying head checks the surface for manufacturing defects and also measures the magnetic recording ability of the substrate.

The invention involves a method of preparing a thin lubricant film using plasma-enhanced chemical vapor deposition on the top of carbon overcoat of magnetic storage media. Just as solids, liquids and gases are states of matter, plasma is a state of matter. Specifically, plasma is ionized gas. That is, gas that has been given an electrical charge by being stripped of electrons.

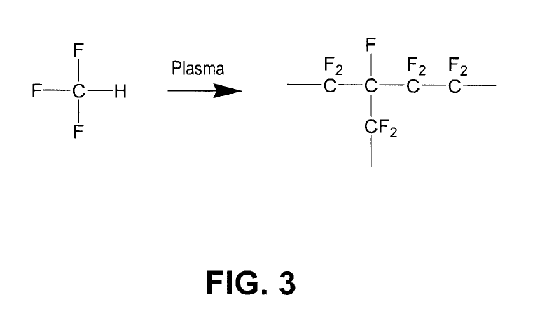

The plasma polymerization process uses a fluorocarbon precursor, preferably containing more than two carbon atoms, small amount of oxygen and a hydrocarbon stabilizer. The resulting film has very low surface energy, good thickness uniformity and good scratch resistance for post-lubing processes. PECVD of fluorocarbon thin film usually gives highly cross-linked polymers. For example, FIG. 3 shows a schematic PECVD polymerization of trifluoromethane.

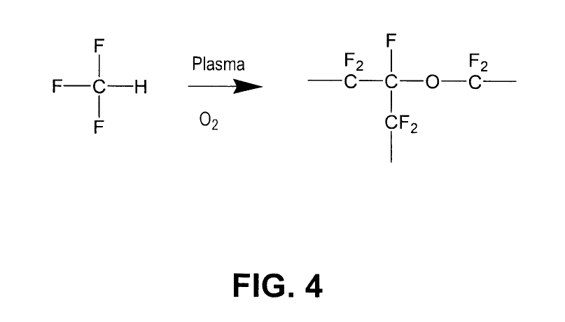

The cross-linked perfluorocarbon polymers could have weak wear resistance because of the rigid chemical structure, little molecular mobility to relax shear stress applied during post-lubing processes. The inventors recognized that by inserting ether units between perfluorocarbon one could possibly reduce the rigidity of the polymers. FIG. 4 shows the plasma polymerization of trifluoromethane in the presence of oxygen to form a solid lubricant film of this invention. The resulting polymer is a cross-linked perfluoropolyether is substantial flexibility.

The presence of oxygen during the plasma reaction shown in FIG. 4 generates highly active oxygen radicals and ions, which could etch the surface film. To turn down the reactivity of oxygen plasma, the inventors found that a hydrocarbon gas could be added to the plasma system as a stabilizer. By controlling the amount of hydrocarbon, including methane, ethane, propane, butane, pentane, hexane, etc., etching can be entirely inhibited.

The process flow rates of trifluoromethane, oxygen and hydrocarbon depend upon the plasma system. Oxygen and Hydrocarbon contents in the plasma process chamber are controlled in the range of 1% to 30%. The process temperature ranges from 20 to 150 C and the pressure ranges from 0.1 to 10 Torr.

The inventors unexpectedly found during the course of this invention that a solid lubricant film of perfluoropolyether could be formed when the plasma system was maintained at a temperature between room temperature to 150° C. When the temperature of the plasma system was greater than 150° C., the film tended to degrade. A rapid surface energy increase of the deposited film is observed as the process temperature exceeds 150 C.

Furthermore, the degree of cross-linking could be reduced by selecting fluorocarbon precursors with longer carbon chain. For example, plasma polymerization of decafluoropentane gives longer perfluorocarbon segments than that of trifluoromethane. The preferred carbon chain length of the fluorocarbon precursors is 2 to 10.

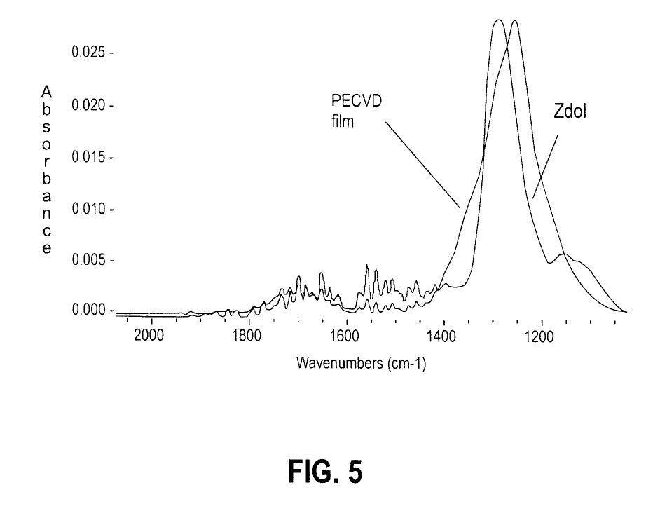

FIG. 5 is the FTIR spectra of a PECVD film and a perfluoropolyether (PFPE) lubricant, Zdol. The PECVD and Zdol lubricant films were deposited on carbon overcoat on normal magnetic storage medium. The Zdol film was deposited using normal dip-lubing process. The PECVD film was deposited according to the method disclosed in this invention. The FTIR spectrum indicates that the PECVD film has similar chemical composition to Zdol. In particular, the ESCA element analysis of the PECVD film deposited using decafluoropentane shows that there is one oxygen atom per 10 fluorine atoms, which indicates one ether linkage on each end of decafluoropentanyl segment in the film.

Zdol is a liquid lubricant that currently applied to recording media. Zdol includes polyfluoroether compositions that may be terminally functionalized with polar groups, such as hydroxyl, carboxy, or amino. The polar groups provide a means of better attaching or sticking the lubricant onto the surface of the recording media. Zdol and other fluorinated oils are commercially available under such trade names as Fomblin Z®, Fomblin Z-Dol®, Fomblin Ztetraol®, Fomblin Am2001®, Fomblin Z-DISOC® (Montedison); Demnum® (Daikin) and Krytox® (Dupont). The chemical structures of some of the Fomblin lubricants are shown below.

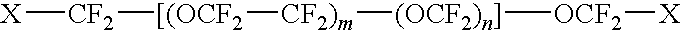

Fomblin Z: Non-reactive end groups

X═F

Fomblin Zdol Reactive end groups

X═CH₂—OH

Fomblin AM2001: Reactive end groups

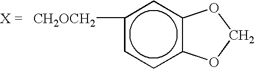

Fomblin Ztetraol Reactive end groups

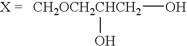

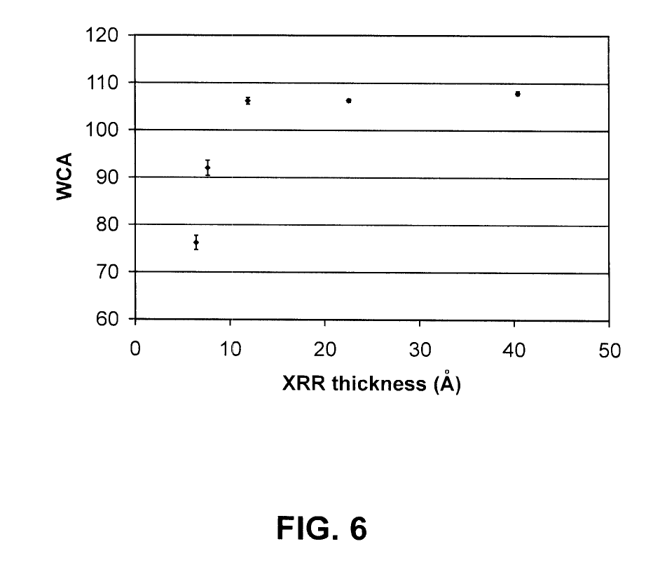

The PECVD deposited film had a low surface energy. The water contact angle (WCA), a measurement of surface energy, showed that a film of the PECVD having a thickness of about 12 Å had a WCA as high as 106 (FIG. 6). Excellent thickness uniformity can also be achieved. As little as ±0.5 Å thickness variation was observed across full disk surface.

The thickness of the solid lubricant coating should be preferably in the range of 7 to 40 Å.

The solid lubricant film of this invention besides being solid also has the following desirable properties. The film contains no solvent or liquid that could evaporate. The liquid lubricant could spin-off a disc under fast rotation. The solid lubricant film does not spin-off under fast rotation. Also, a liquid lubricant could be picked-up by the recording head of the disc drive. This lube pick-up problem is prevented by the use of the solid lubricant. Also, under high speed rotation of the disc drive, a liquid lubricant could form ripples. Such ripple formation is prevented by the use of a solid lubricant.

In addition, to the above advantages, the solid lubricant film of this invention could be burnished and buffed without destroying or removing the solid lubricant film. The methods of polishing, burnishing and buffing the surface of the non-magnetic substrate of a recording medium are disclosed in U.S. Pat. No. 6,503,405, which is incorporated herein by reference.

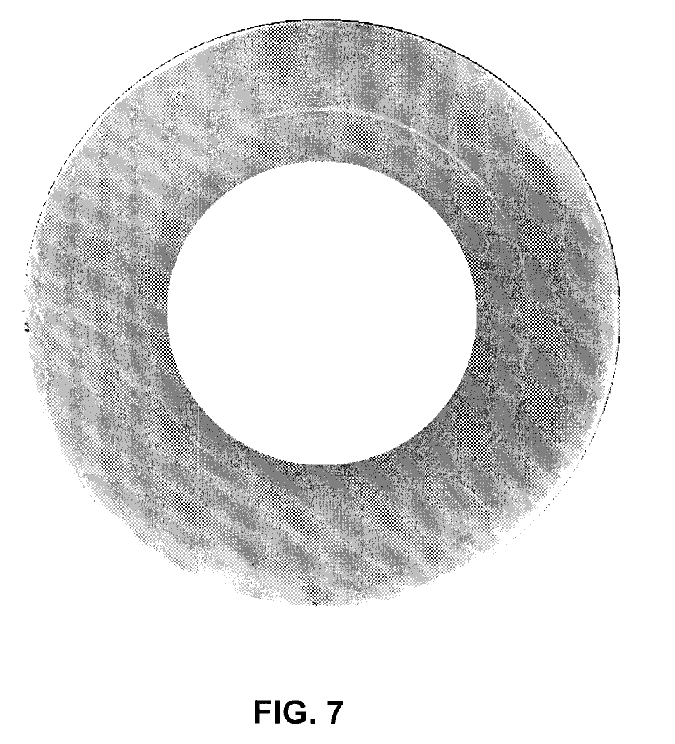

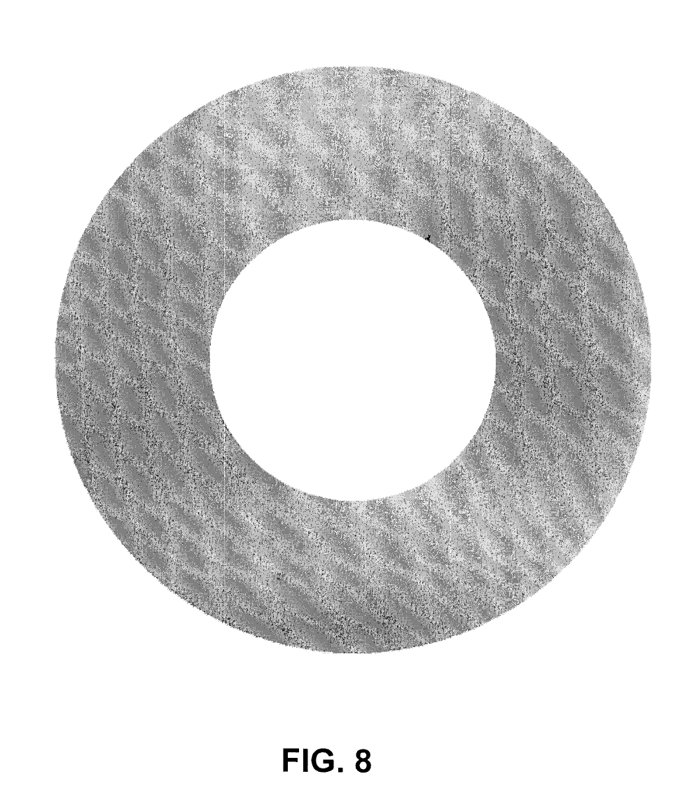

The inventors unexpectedly found that a solid PECVD lubricant film of cross-linked perfluoropolyether of FIG. 4 has substantially better wear resistance during burnishing and buffing than a solid PECVD film of FIG. 3 when both films were exposed to identical burnishing and buffing conditions. The unexpected results are clearly demonstrated in FIGS. 7 and 8. In particular, a PECVD film using only trifluoromethane in the plasma process was prone to scratching and de-bonding during post-lubing process as shown in FIG. 7. On the other hand, a film deposited using decafluoropentane as a precursor, oxygen as an ether linkage generator, and hexane as a process stabilizer exhibited much a strong resistance to scratching and de-bonding as shown in FIG. 8.

The PECVD film using trifluoromethane alone as precursor has very weak scratch resistance. Post-lubing buffing leaves scratch marks all over the disk surface (FIG. 7). The film deposited based on this invention has much better scratch resistance. No scratch is found on disks after post-lubing buffing.

In this application, the word “containing” means that a material comprises the elements or compounds before the word “containing” but the material could still include other elements and compounds. This application discloses several numerical ranges in the text and figures. The numerical ranges disclosed inherently support any range or value within the disclosed numerical ranges even though a precise range limitation is not stated verbatim in the specification because this invention can be practiced throughout the disclosed numerical ranges.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein. Finally, the entire disclosure of the patents and publications referred in this application are hereby incorporated herein by reference.

What is claimed is:

1. A method of manufacturing a magnetic recording medium, the method comprising:
forming a magnetic recording layer on a substrate;
and
forming a first layer on the magnetic recording layer via plasma-enhanced chemical vapor deposition, the first layer comprising perfluoropolyether, wherein plasma-enhanced chemical vapor deposition comprises exposing the magnetic recording layer to an atmosphere comprising plasma and a gas including fluorine-on the magnetic recording layer.

2. The method of claim 1, wherein the atmosphere further comprises oxygen and a hydrocarbon.

3. The method of claim 1, wherein the atmosphere is maintained at a temperature of approximately 150° C. or less during the formation of the first layer on the magnetic recording layer.

4. The method of claim 1, wherein the fluorine is trifluoromethane and the atmosphere further comprises a hydrocarbon gas.

5. The method of claim 1, wherein the first layer comprises a polymer comprising:

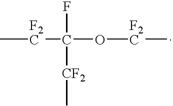

6. The method of claim 5, wherein the polymer comprises at least one oxygen per 1 to 10 carbon atoms.

7. The method of claim 5, wherein the polymer comprises ether linkages between decafluoropentanyl segments.

8. The method of claim 1, wherein the first layer comprises a lubricating layer.

9. The method of claim 1, further comprising depositing a carbon overcoat layer on the magnetic recording layer, wherein the carbon overcoat layer is between the magnetic recording layer and the first layer.

10. The method of claim 1, wherein the first layer has a water contact angle of greater than approximately 75 degrees.

11. The method of claim 1, wherein the first layer has a room temperature water contact angle of greater than approximately 100 degrees.

12. The method of claim 1, wherein the first layer is substantially free of liquid.

13. The method of claim 1, wherein the first layer has a thickness between approximately 7 angstroms and approximately 40 angstroms.
